(19) United States
(12) Patent Application Publication
(10) Pub. No.: US 2007/0152674 A1
(43) Pub. Date: Jul. 5, 2007

(54) Thermal Energy Management of Electronic Devices

(76) Inventor: David Allen Hubbell, Fort Walton Beach, FL (US)

Correspondence Address: MARY HUBBELL, PO BOX 171, FORT WALTON BEACH, FL, 32549, US

(21) Appl. No.: 11/565,857

(22) Filed: Dec. 1, 2006

Related U.S. Application Data
(60) Provisional application No. 60/742,177, filed on Dec. 2, 2005.

(51) Int. Cl. G01R 31/14

(52) U.S. Cl. 324/509

(57) ABSTRACT

The present invention utilizes solid-state components'/devices' electrically-conductive elements as means for transport of thermal-energy via the application of the Thomson Effect through affecting a change in temperature, such as in the electrical power supply leads. Application may be at electrical current characteristics below that required to energize said solid-state components/devices to achieve intended solid-state utility output. The present invention applies Tesla's phase-change conductive/non-conductive, both of an electrical and/or thermal nature, to the present art of solid-state electronics' individual integrated circuit elements, printed wiring boards, insulating layer(s), and pillars for the optimizing of the thermal-energy-management of such. The present invention analyzes three-dimensional thermal volumes of solid-state items and effecting change of temperature via said items' electrical pathway(s) and/or by effecting said pathways by altering the matter-phase of such pathways resulting in change in conductivity/non-conductivity, both of an electrical and/or thermal nature, of said pathways.

### RELATED U.S. APPLICATION DATA

This application claims the benefit of Provisional Application Ser. No. 60/742,177 filed Dec. 2, 2005

| | | |
|---|---|---|
| PCT/IS2003/000032 | WO 2004/038290 A1 | Jonsson et al. |

### U.S. PATENT DOCUMENTS

| | |
|---|---|
| U.S. Pat. No. 151,568 | Clamond |
| U.S. Pat. No. 214,637 | Edison |
| U.S. Pat. No. 413,136 | Dewey |
| U.S. Pat. No. 2,856,160 | Kaye & Hatsopoulos. |
| U.S. Pat. No. 2,930,904 | Fritts |
| U.S. Pat. No. 3,017,522 | Lubcke |
| U.S. Pat. No. 3,091,939 | Baude |
| U.S. Pat. No. 3,248,889 | Zimmermann |
| U.S. Pat. No. 3,481,393 | Chu |
| U.S. Pat. No. 3,308,629 | Sharp. |
| U.S. Pat. No. 5,663,719 | Deese, et al. |
| U.S. Pat. No. 6,422,714 | Hubbell |
| U.S. Pat. No. 6,676,279 | Hubbell, et al. |
| U.S. Pat. No. 6,682,211 | English, et al. |
| U.S. Pat. No. 6,705,744 | Hubbell, et al. |
| U.S. Pat. No. 6,937,958 | Gold, et al. |
| U.S. Pat. No. 7,134,193 | Sasaoka, et al. |
| U.S. Pat. No. RE-11,865 | Tesla |

### OTHER REFERENCES:

Electrical Engineering In Theory And Practice, by G. D. Aspinall Parr, MacMillan and Co., © 1906
Solid State Physics, by Om Parkash Pahuja, Laxmi Publications LTD, © 2005
U.S. Air Force Small Business Innovation Research (SBIR) Proposal # AF06-153, Title: Novel Thermal Management Solutions for Confined Electronics, Open Date: Dec. 13, 2005.
U.S. Navy Small Business Innovation Research (SBIR) Proposal # N07-086, Title: High-Efficiency Thermoelectric Generator, Open Date: Dec. 6, 2006
U.S. Air Force Small Business Innovation Research (SBIR) Proposal # AF071-183, Title: Nanofluids for Heat Transfer Enhancement in Aircraft Systems, Open Date: Dec. 6, 2006.
Nano, Quantum And Molecular Computing: Implications To High Level Design And Validation, by Sandeep Kumar Shukla, R. Iris Bahar © 2004 Kluwer Academic Publishers
Heat Transfer Handbook, by Joseph H. Boyett, Adrian Bejan, Allan D. Kraus Copyright © 2003 by John Wiley & Sons, Inc.
Handbook of Reliability Engineering and Management, by William Grant Ireson, Clyde F. Coombs, Copyright © 1996 by The McGraw-Hill Companies
Carbon Nanotubes: Science and Applications, by M. Meyyappan Meyyappan, Laurie Kelly, © 2005 by CRC Press LLC
Practical Guide to Rotational Moulding, by Roy J. Crawford, Mark P. Kearns © 2003, Rapra Technology Limited
Introduction to Cold Regions Engineering, by Dean R. Freitag, Terry T. McFadden Copyright © 1997 by the American Society of Civil Engineers
Theory and Calculation of Electric Circuits, by Charles Proteus Steinmetz Copyright, 1917, by the McGraw-Hill Book Company, Inc.

### FIELD OF THE INVENTION

In all thermal-energy-management present art, the delivery of electrical power is considered separate from the management of radiation of thermal energy produced by the distribution and partial conversion of said electrical power. That is, while the undesirable heat generated by the flow thru and partial conversion of electricity by a solid-state device originates in the conductive and semi-conductive materials components of the solid-state device in question, the present art only addresses means and methods of the unwanted heat generated after said heat traverses the non-conductive materials components of said device. For example, in the present art of removing unwanted heat from solid-state devices, such as LEDs, the unwanted heat generated by the partial conversion of electricity, within the LED device, into light and heat, the unwanted heat is transported by creating a thermal-gradient across the required non-conductive enclosure of the LED's circuitry and power supply leads which allows for the partial conversion of the supplied electricity to take place. The present invention relates generally to solid-state electronic devices such as light emitting diodes (LED) or very large scale integration (VLSI) components, such as microprocessors. The present invention addresses use of traditional metallic solid-state electronic power supply leads/circuitry, non-traditional non-metallic power supply leads/circuitry and thermally sensitive phase-change electrically conductive/non-conductive component(s) power supply leads/circuitry for effecting thermal-energy-management of saidsame devices and extraction and/or injection of thermal-energy thru/into saidsame devices.

### BACKGROUND OF THE INVENTION

The need for thermal-energy-management of things electrical predates solid-state electronics. An example is the Apr. 22, 1879, U.S. Pat. No. 214,637 issued to Edison, in which Edison teaches that his (page 1, paragraph 3) “ . . . invention consists in causing the heat generated by the incandescent conductor to expand the air or fluid in the containing chamber as its temperature rises, the pressure thus created serving to move outwardly a yielding material—such as a diaphragm—which, in its turn, serves to control the passage of the electric current through the incandescent body by means of contact-points or circuit-regulators, and thus the temperature of the incandescent conductor will be regulated automatically.”

A representative echo of Edison's teachings on thermal-energy-management at the dawn of the solid-state electronic era is found in the Mar. 29, 1960, U.S. Pat. No. 2,930,904 issued to Fritts who teaches that (col. 1, line 21) “Certain electrical devices utilize therein an element in the form of a body of crystalline material having electrical properties which vary substantially with temperature. Two examples of this type of device are rectifiers and transistors, each utilizing semiconductor crystalline bodies in which heat is generated during normal operation. This heat, unless removed, has a marked deleterious effect on the operating characteristics of these devices, lowering the efficiency thereof to a very substantial degree. Moreover, devices of this type must be operated within well defined, relatively low temperature maximum limits in order to be operative at all.”

Ireson and Coombs (Handbook of Reliability Engineering and Management) provide a 1996 review of the then present art semiconductor and engineering issues: (Page 14.2) “The electrical characteristics of any device depend upon the device's material properties and design. A resistor, for example, relies on the resistivity of the material chosen to form the resistor and the shape of the resistor to determine the specific resistance level.” “The semiconductor junction is the heart and soul of virtually each modern active circuit, integrated or otherwise.” “A junction with no externally applied potential is in a state of dynamic balance. A small voltage in the forward direction immediately upsets that balance . . . ” (Page 14.3) “Electrical overstress . . . ” EOS “ . . . is exactly what the term says. Electrical energy delivered to a part simply overwhelms the part and causes it to fail. It causes the failure by raising the temperature of some portion of the device to a point where material undergoes a phase change . . . ” The electrical energy in an EOS event is delivered to a part by the mechanism of Joule heating, i.e. the familiar I²R relationship, where I and R are current and resistance, respectively.” “Once a portion of a material is warmer (or cooler) than its surroundings, thermal energy flows into or out of the localized volume. It does this for exactly the same reasons a concentration of material diffuses from one region to another. In the case of thermal energy, the flux of heat crossing a unit area is proportional to the gradient in temperature, . . . ”

Freitag and McFadden (Introduction to Cold Regions Engineering) teach that (Page 158) “Thermal conductivity is a measure of the quantity of heat that will flow through a unit area of a substance of unit thickness in a unit time under a unit temperature gradient . . . . The thermal conductivity of ice is much greater than water . . . ” “Heat Capacity is the amount of heat required to raise the temperature of a unit mass of a substance by one degree.” “Water is a good conductor of electrical signals but ice is not.”

Boyett, Bejan and Kraus (Heat Transfer Handbook), provide a 2003 general statement on the then present art of thermal-energy-management and specific reference to thermal management of microprocessors: (Page 2) “Practitioners of the thermal arts and sciences generally deal with four basic thermal transport modes: conduction, convection, phase change, and radiation. The process by which heat diffuses through a solid or a stationary fluid is termed heat conduction. Situation in which heat transfer from a wetted surface is assisted by the motion of the fluid give rise to heat convection, and when the fluid undergoes a liquid-solid or liquid-vapor state transformation at or very near the wetted surface, attention is focused on this phase-change heat transfer. The exchange of heat between surfaces, or between a surface and a surrounding fluid, by long-wavelength electromagnetic radiation is termed thermal heat radiation.” (Page 4) “Heat transfer across the interface between two solids is generally accompanied by a measurable temperature difference, which can be ascribed to a contact or interface thermal resistance. For perfectly adhering solids, geometrical differences in the crystal structure (lattice mismatch) can impede the flow of phonons and electrons . . . ” (Page 164) “ . . . characterization of conduction heat transfer, which is a mode that pervades a wide range of systems and devices. Unlike convection, which pertains to energy transport due to fluid motion and radiation, which can propagate in a perfect vacuum, conduction requires the presence of an intervening medium. At microscopic levels, conduction in stationary fluids is a consequence of higher-temperature molecules interacting and exchanging energy with molecules at lower temperatures. In a nonconducting solid, the transport of energy is exclusively via lattice waves (phonons) induced by atomic motion. If the solid is a conductor, the transfer of energy is also associated with the translational motion of free electrons.” . . . “Because the thermal conductivity depends on the atomic and molecular structure of the material, its value can vary from one material to another by several orders . . . ” (Page 264) “When two solids are joined, imperfect joints (interfaces) are formed. The imperfect joints occur because “real” surfaces are not perfectly smooth and flat. A mechanical joint consists of numerous discrete microcontacts that may be distributed in a random pattern over the apparent contact area if the contacting solids are nominally flat (conforming) and rough, or they may be distributed over a certain portion of the apparent contact area, called the contour area . . . . Microgaps and macrogaps appear whenever there is absence of solid-to-solid contact. The mircogaps and marcogaps are frequently occupied by a third substance, such as gas (e.g., air), liquid (e.g., oil, water), or grease, whose thermal conductivities are frequently much smaller than those of the contacting solids.” (Page 574) “Radiative heat transfer or thermal radiation is the science of transferring energy in the form of electromagnetic waves. Unlike heat conduction, electromagnetic waves do not require a medium for their propagation. Therefore, because of their ability to travel across vacuum, thermal radiation becomes the dominant mode of heat transfer in low pressure (vacuum) and outer-space applications. Another distinguishing characteristic between conduction (and convection, if aided by flow) and thermal radiation is their temperature dependence. While conductive and convective fluxes are more or less linearly dependent on temperature differences, radiative heat fluxes tend to be proportional to differences in the fourth power of temperature (or even higher). For this reason, radiation tends to become the dominant mode of heat transfer in high-temperature applications, . . . ” (Page 950) “Throughout the 1990s, heat-sink-assisted air cooling was the primary thermal packaging approach for the cost/performance category, which included both desktop and notebook computers. Thermal management of the microprocessors used in desktop computers often relied on clip-attached or adhesively bonded extruded aluminum heat sinks, cooled by remotely located fans.” (Page 1311) “The free electrons are typically responsible for thermal transport in metals . . . . In an insulating material, thermal transport is accomplished through the motion of lattice vibrations called phonons . . . . The primary heat carriers in semiconductor materials are also phonons, and therefore the thermal transport properties of semiconductors are determined in the same manner as for insulating materials.” (Page 1312) “ . . . materials that are good electrical insulators are typically also good thermal insulators. As . . . example, high-power diode lasers and, particularly, vertical cavity surface-emitting laser diodes are often limited by the dissipation of thermal energy. These devices are an example of the increased trend toward multilayer thin-film structures. Recently, developers of thermoelectric materials have been using multilayer superlattice structures to reduce thermal transport normal to the material. This could significantly increase the efficiency of thermoelectric coolers.” “In metals, thermal transport occurs primarily from the motion of free electrons, while in semiconductors and insulators, thermal transport occurs due to lattice vibrations that travel about the material much like acoustic waves.”

Crawford and Kearns (Practical Guide to Rotational Moulding) expand on Boyett, Bejan and Kraus' 2003 statement: (Page 163) “ . . . poor thermal conductivity in . . . plastic causes large thermal gradients across the plastic . . . . Chemists and physicists are starting to learn how to control electrical conductivity in plastics. Similar efforts are needed to enable us to increase and reduce the thermal conductivity of plastics. The use of additives, perhaps at the ‘nano’ level may be a factor here although chemical modification of the structure of plastics is also likely to play a role. Since thermal insulation of . . . plastic parts is a characteristic that it may be desirable to retain, it is control of the thermal properties that will be the key. Low resistance to heat transfer when shaping is taking place but good insulation properties in the solid state is what is needed . . . ” Page 164, “It is well known that materials that undergo a phase change can transfer large amounts of heat.”

Shukla and Bahar (Nano, Quantum And Molecular Computing: Implications To High Level Design And Validation) provide a 2004 statement of the then semiconductor present art and engineering challenges: (Page 6) “The semiconductor industry has enjoyed the fruits of scaling; but with shorter and shorter devices the problems of scaling are becoming more and more predominant.” (Page 7) “Short channel effect in scaled MOSFET devices is the lowering of the threshold voltage Vₜₕ with decreasing channel length . . . In long-channel devices, the source and drain are separated far enough that their depletion regions have no effect on the potential or field pattern in most part of the device, and hence, the threshold voltage is virtually independent of the channel length and drain bias. In a short-channel device, however, the source and drain depletion width in the vertical direction is comparable to the effective channel length. This causes the depletion regions from the source and the drain to interact with each other. The obvious consequence of this is lowering of the potential barrier between the source and the channel. This causes lowering of the threshold voltage of the MOSFET with decreasing channel length, a phenomenon referred to as short channel effect . . . ” “Apart from the channel length, the drain voltage also has a significant effect on the potential barrier for short channel devices. Under off conditions, this potential barrier between the source and the channel prevents electrons from flowing to the drain. For a long-channel device, the barrier height is mainly controlled by the gate voltage and is not sensitive to V_{ds}. However when a high drain voltage is applied to a short-channel device, barrier height is lowered resulting in further decrease of the threshold voltage. The source then injects carriers into the channel surface without the gate playing a role. This is know as drain induced barrier lowering (DIBL). DIBL is enhanced at higher drain voltage and shorter effective lengths. Surface DIBL typically happens before deep bulk punch through.”

Meyyappan and Kelly (Carbon Nanotubes: Science and Applications) provide a 2005 review of then present art nanotube, applications and potential solutions to engineering challenges: (Page 277) “Whereas carbon nanotube (CNT)-based electronics may be a long-term prospect awaiting further development . . . there are areas where CNTs can provide possible solutions to anticipated problems in the future generations of . . . integrated circuit (IC). . . . One such area involves interconnects, which is currently dominated by copper damascene processing . . . . Copper replaced aluminum about 5 years ago due to its higher conductivity. The industry has developed successful processing techniques to integrate Cu interconnects because it is notoriously difficult to etch. The current problem with copper interconnects appears to be electromigration when current densities reach or exceed 10⁶ A/cm² . . . In contrast, CNTs do not suffer even at current densities 10⁷ to 10⁹ A/cm² . . . and can offer a solution to the interconnect problem.” “It is well known that heat-dissipation issues are becoming critical with every new generation of computer chips, with current levels exceeding 50 W/cm². CNTs exhibit very high-thermal conductivities in the range of 1200 W to 3000 W/mK depending on single-wall nanotube (SWNT) or multiwall nanotube (NWNT) diameter, etc. . . . The high-thermal conductivity of CNTs is also useful in heat dissipation in several other industrial instruments, though at this writing no industrial applications have been demonstrated.” (Page 278) “Filling of the nanotubes with various metals has been studied for producing wires and other applications . . . . Although no conductivity data were reported, Cu-filled nanotubes may be useful in interconnect and heat-dissipation applications. Small spherical crystals and elongated single crystals of Ru have also been filled inside nanotubes using wet chemistry . . . . Except in the case of Li, most studies concentrated on demonstrating an approach to fill the nanotubes without any particular application in mind.” “The nanoscale size and hollow core of CNTs have prompted research into applications such as . . . nanofluidic channels . . . and other molecule delivery systems. Most of the early and current studies have focused on the fluid transport through these nanochannels . . . diffusivities of light gases in nanotubes . . . concluded that the transport rates in nanotubes are orders of magnitude higher than those in zeolites.”

An expression of the present art of thermal-energy-management problem-set is found in U.S. Air Force Small Business Innovation (SBIR) Proposal # AF06-153, Title: Novel Thermal Management Solutions for Confined Electronics, which reads in part, “One of the challenges associated with decreasing volume and increased performance demands is the generation of heat by electronics in a confined space . . . As temperature increases, semiconductor-based electronics begin to lose function and can ultimately fail. Compounding the problem, the volumetric power generation increases linearly with the inverse volume while other heat transfer properties, such as the heat transfer coefficient between a heat sink and a confined air volume, scale differently with characteristic dimensions and are strongly dependent on geometry . . . . System thermal management for electronic systems is generally accomplished through a combination of passive design (i.e., optimizing the layout of the boards, integrated circuit elements, supporting structures, etc.) and active cooling. However, the limited available volume . . . and large number of required critical components creates a significant challenge for miniaturiz(ation) . . . only a limited number of configurations are possible that maintain the designed functionality . . . . Electronics in miniaturized . . . ” devices “ . . . are thus approaching a critical threshold where the power density exceeds the ability to effectively manage the heat flow with conventional solutions. An additional complication is the need to implement this solution in a cost-effective and easily-maintained manner.”

The present invention addresses the problem-set identified by the above SBIR # AF06-153 Proposal and articulated by U.S. Pat. No. 3,481,393, issued Dec. 2, 1969, to Chu. Chu teaches that (col. 1, line 35) “(i)t is known that the reliability of electronic devices such as semiconductor transistors or diodes decrease with increasing temperature. Also, it is known that the operating characteristics of such devices vary appreciably over the temperature range of operation so that the performance will begin to deteriorate to a degree rendering the device unusable for many purposes long before such a temperature causing a complete failure has been reached.”

Chu identifies three difficulties of the present art of thermal-energy-management of present day electronic components and electric devices constructed from said electronic components. Quoting Chu, the (col. 1, line 63) “ . . . problem has been to obtain a flush fit of each of the electronic modules on the large surface of the cold plate so that there is good heat conduction therebetween. A further problem has been the limitation on size of the modules, especially of the plug in type, in that each module must be of the same height in order to be adaptable to the common cold plate. A further serious limitation is that each of the electronic modules connected to a common cold plate must necessarily be of substantially the same power requirements since there is no local means of varying the cooling available.”

The present invention addresses each of Chu's identified problem-set issues which are:
1) use of specific thermally conductive structures, such as Chu's “ . . . flush fit . . . on the surface . . . of . . . cold plate . . . ” providing “ . . . good heat conduction . . . ” Said thermally conductive structures, in present art electronics being electrically insulated from said electronic's power supply leads and circuitry.
2) requirement of present art electronic components' physical structure to be accommodating to specific, structurally-and-electrically-independent, thermally conductive structure(s) associated with the specific electronic component's thermal-energy-management, Chu providing a specific example of such wherein “ . . . each module must be of the same height . . .
3) use of a thermal-energy-management thermally conductive structure providing only a few exit avenues for unwanted heat from a given electronic component or device consisting of multiple electronic components, Chu providing the specific example of the use of a “ . . . common cold plate . . . ”

Present art solid-state electronic design of incorporating multiple layers of specific circuitry in which said layers are interconnected for electronic function has evolved Chu's principally two-dimensional thermal-energy-management problem-set into a three-dimensional, “thermal-volume”, thermal-gradient design problem-set. That is, whereas Chu's mid-1960's thermal-energy-management design of electronics requirements primarily involved moving unwanted heat from a single surface and thereby allowing the use of the third-dimension as an avenue for transporting said unwanted heat away from said surface, present day “built-up” electronic devices of multiple layers of individual electronic “surfaces” presents a design which precludes the use of the third-dimension independent of structural considerations of said electronic surfaces.

The present inventor's U.S. Pat. No. 6,676,279, issued Jan. 13, 2004, to Hubbell, et al. (Hubbell '279) points out that in the case of solid-state LEDs (col. 2, line 62) “ . . . mounted on a typical circuit-board . . . ” that the waste-heat generated “ . . . tend(s) to radiate more heat on the circuit-board side as opposed to the illumination generation side. That is, in the case of LED's mounted on a typical circuit-board, a majority of the waste-heat generated originates not on the LED circuit side but rather on the “backside” of the circuit board.” The present art using “very large scale integration” (VLSI) components, for such devices as microprocessors tends to trap said waste-heat between layers of circuitry surfaces.

A recent expression of Chu's problem-set in three-dimensions is found in U.S. Pat. No. 7,134,193, issued Nov. 14, 2006, to Sasaoka, et al. (Sasaoka) Paraphrasing Sasaoka, U.S. Pat. No. 7,134,193 teaches of an apparatus for manufacturing multi-layered wiring boards having interlayer connections made by conductive pillars and said individual layered boards having a conductive foil and an apparatus for manufacturing a multi-layered wiring board having a conductive foil having conductive pillars laminated with an insulating resin layer. Quoting Sasaoka's Description of the Related Arts, “Demands for high-density mounting of electronic elements are increasing as various types of electronic equipment are made compact and highly advanced in performance. In response to such demands, a type of wiring board, such as printed wiring board being used extensively is a multi-layered wiring board which has a laminated structure with insulating layers and wiring layers alternately overlaid.” The present invention provides thermal-energy-management for such multi-layered wiring boards or three-dimensional solid-state devices thru the dual use of electrical circuitry for both the traditional use of supplying electrical-energy and for the novel transport of heat-energy from within multi-layered boards' laminated structures and thru the present art requirement of such multi-layered boards' insulating layers. The present art of extracting unwanted heat-energy from three-dimensional solid-state devices is to either include in the structure of the device thermally-conductive but not electrically-conducting passages to transport said heat-energy out of the solid-state device's interior or to simply induce a significant thermal-gradient between said device's interior and said device's exterior or a combination of the two. The present art incorporates thermal-passages designed for the use of liquids or gases to absorb unwanted interior heat and transport said liquid or gas, with said absorbed heat to the exterior of said solid-state device. Such thermal-passages both complicate the design and manufacture of three-dimensional solid-state devices and, as said unwanted heat is almost always the by-product of the devices' intended conversion of electrical-energy into the desired output (such, for example, as in the case of LEDs where supplied electrical-energy is partially-converted into light-energy, the conversion of which results in the aforementioned unwanted heat-energy) said thermal-passages, by design, are required to be electrically-insulated and physically separated from the source-point of the unwanted heat-energy, and thus a thermal-gradient is required to be created across said electrically-insulated physical boundary to extract said unwanted heat-energy. Further, the volume within the three-dimensional solid-state devices taken to provide said unitary-use thermal-passages constrain the density of desired solid-state elements for a given device's volume. By utilizing electrical circuitry for both supply of electrical-energy and convey of unwanted heat from a three-dimensional solid-state device's interior, for the same given device volume, larger dimensional electrical circuitry is possible thereby improving the dual use of such circuitry. More volume may be given over to the primary purpose of the device. One may either increase the density of the unit or increase the volume-efficiency of the unit to provide more electronic circuitry along with more efficient removal of unwanted heat.

The general concept of present invention's use of electrical circuitry as a thermal-energy transit means is taught in present art such as U.S. Pat. No. 413,136, issued Oct. 15, 1889, to Dewey. Dewey teaches the application of the Thomson Effect. Quoting Dewey, (page 1, line 10) “The object of my invention is to produce cold by the electric current in such quantities that food may be preserved, ice kept from melting, water frozen, and rooms or receptacles cooled.” (page 1, line 15) “My invention consists in establishing an electric circuit having one or more parts adapted to be cooled and one or more parts adapted to be heated by the current therein, locating the cooled part or parts within or in contact with a receptacle, insulating the receptacle from the influence of heat on the exterior thereof, diffusing, conducting, or dissipating the heat from the heated part or parts of the circuit, and exposing the substance to be cooled within said receptacle.” (page 1, line 51) “FIG. 7 shows a cooling or freezing apparatus based on the Thomson effect.” (page 2, line 126) “FIG. 7 shows an electric circuit which has cooling parts in connection with or leading through the receptacle several times; but said circuit is formed of but one metal or alloy throughout. This metal may be iron. The effect of a current flowing in an iron circuit is to exaggerate or increase differences of temperature therein. a a a represent the parts to be cooled or to absorb the heat from the receptacle A, and are located therein, and a′ a′ a′ are the parts to which the heat is conducted or convected by the current and then radiated or diffused therefrom. The said parts are shown as and may be in some cases spirals or coils, but in other cases may be straight or simply waved. The exterior or warm coils a′ are heated at the commencement of the operation by applying heat from some external source, as gasjets, an electric heating device, or, what is the same thing, cooling the interior of the receptacle by locating ice or a freezing mixture therein. Said coils may be maintained at a higher temperature than those on the interior by reducing the cross-section of the conductor forming them—that is, forming them of smaller wire than the balance of the circuit. After the heat is once located in the warm parts said heat will generally be maintained without a further application of external heat, simply through the convection. The heat should not in this case be dissipated too rapidly or the difference between the temperatures in the said parts will be sufficiently great to produce a rapid effect. The conductor forming the circuit may be insulated from the receptacle and the latter insulated from heat on the exterior thereof, as before described. The warm coils may be located at some distance from the receptacle.”

The present invention's utilization of the Thomson Effect to transport unwanted heat-energy from the interior of a three-dimensional solid-state device via said three-dimensional solid-state device's electrical-supply-circuitry is not limited to when said device is in operation. Most solid-state devices have relatively high electrical current characteristics threshold before said solid-state device is energized and the desired output is achieved. An example is taught in U.S. Pat. No. 5,663,719, issued September 1997, to Deese, et al. Deese provides solutions for the Deese, et al., U.S. Pat. No. 5,457,450 (issued 1995) problem statement that “(w)henever the power supply to a given area is disrupted, for whatever reason, so that the supply voltage drops to a brownout condition (approximately 92 volts alternating current (AC)), these LED . . . lights will not produce sufficient light . . . ” The present invention provides for pre-chilling of solid-state device interiors by using Thomson Effect on said device's electrical-circuitry at voltages below that required to energize said solid-state device.

One method of enhancing the above referenced Thomson Effect is incorporation of present art thermoelectric devices to create thermal-gradient along a solid-state device's electrical-supply-circuitry and to use such concept to enhance the thermoelectric devices used. One of the first to address the present art of thermoelectric devices is U.S. Pat. No. 151,568, issued Jun. 2, 1874, to Clamond. Clamond teaches that (page 1, paragraph 3) “(i)t is noticeable that thermoelectric bars, as heretofore made, preserve their property for but a short time. Under the continued action of heat, and the successive heatings and coolings to which they are subjected, they acquire an internal resistance, which constantly increases, while the electric force remains the same, which resistance, in time, becomes such that the current generated, by the heat can give but a very feeble and almost inappreciable quantity of electricity. Sometimes, indeed, there takes place even a complete solution of continuity, which reduces the electric effect to almost nothing.” Clamond teachings remain valid present art. The present invention provides novel, not apparent, means and methods directly addressing Clamond's referenced “ . . . acquire(d) . . . internal resistance . . . ” via said present day solid-state thermoelectric component's electric power-supply-leads.

Many issued U.S. Patents teach of thermoelectric modules and thermal-energy-management of such thermoelectric modules. Examples are:
U.S. Pat. No. 484,182, issued Oct. 11, 1892, to Dewey
U.S. Pat. No. 2,407,678 issued Sep. 17, 1946, to Ohl
U.S. Pat. No. 2,777,975 issued Jan. 15, 1957, to Aigrain
U.S. Pat. No. 2,898,743 issued Aug. 11, 1959, to Bradley
U.S. Pat. No. 2,992,539, issued Jul. 18, 1961, to Curtis
U.S. Pat. No. 3,055,962, issued Sep. 25, 1962, to Conn

An expression of thermoelectric present art is found in U.S. Navy SBIR Proposal # N07-086, Title: High-Efficiency Thermoelectric Generator, Open Date Dec. 6, 2006 which reads in part, “Significant improvements in thermoelectric performance of semiconductor systems have recently been realized in thin film and bulk materials through the incorporation of nanometer scale structures that significantly increase phonon scattering, leading to record low thermal conductivities. Such performance enhancements have been demonstrated in n-type PbSeTe-based quantum dot superlattice systems prepared by molecular beam epitaxy . . . p-type BiTe—SbTe and n-type BiTe—BiTeSe quantum well superlattices deposited by metal-organic chemical vapor deposition . . . , and bulk n- and p-type LAST (Pb—Sb—Ag—Te) chalcogenides . . . . To maximize system-level conversion efficiency, modules must be designed and materials selected that minimize parasitic losses and maintain mechanical robustness at operating temperature and through repeated temperature cycling.”

Many issued U.S. Patents teaching means and methods of thermal-energy-management of solid-state devices incorporate thermoelectric modules. One of the first U.S. Patents of the solid-state era incorporating thermoelectric technology as a part of a thermal-energy-management arrangement is U.S. Pat. No. 3,017,522, issued Jan. 16, 1962, to Lubcke (col. 1, line 9) “ . . . invention relates to electrical cooling and particularly to means for lowering the operating temperature of a semiconductor electronic valve device.” (col. 1, line 12) “The several desirable attributes of semiconductor devices such as the transistor are well known. However, such devices exhibit undesirable changes in characteristics with temperature and reach inoperability at relatively low temperatures. Inoperability may be induced by electrical power dissipated in the device or may be brought about by elevated ambient temperatures.” Another example is U.S. Pat. No. 3,091,939, issued Jun. 4, 1963, to Baude (col. 1, line 12) “Thermoelectric coolers utilizing the Peltier phenomenon have been known and are sold commercially. . . . These coolers are intended for use as electronic component coolers and for other applications where compactness, silent operation with no moving parts, and a controllable cooling rate is desired.” More current examples are:
U.S. Pat. No. 5,032,897, issued Jul. 16, 1991, to Mansuria, et al.
U.S. Pat. No. 5,229,327, issued Jul. 20, 1993, to Farnworth
U.S. Pat. No. 5,569,950, issued Oct. 29, 1996, to Lewis, et al.
U.S. Pat. No. 5,637,921, issued Jun. 10, 1997, to Burward-Hoy
U.S. Pat. No. 5,714,791, issued Feb. 3, 1998, to Chi, et al.
U.S. Pat. No. 5,956,569, issued Sep. 21, 1999, to Shiu, et al.
U.S. Pat. No. 6,094,919, issued Aug. 1, 2000, to Bhatia
U.S. Pat. No. 6,196,002, issued Mar. 6, 2001, to Newman, et al.
U.S. Pat. No. 6,807,202, issued Oct. 19, 2004, to Plamper, et al.
U.S. Pat. No. 6,847,663, issued Jan. 25, 2005, to Yoon

In all thermal-energy-management present art, the delivery of electrical power is considered separate from the management of radiation of thermal energy produced by the distribution and partial conversion of said electrical power. That is, while the undesirable heat generated by the flow thru and partial conversion of electricity by a solid-state device originates in the conductive and semi-conductive materials components of the solid-state device in question, the present art only addresses means and methods of the unwanted heat generated after said heat traverses the non-conductive materials components of said device. For example, in the present art of removing unwanted heat from solid-state devices, such as LEDs, the unwanted heat generated by the partial conversion of electricity, within the LED device, into light and heat, the unwanted heat is transported by creating a thermal-gradient across the required non-conductive enclosure of the LED circuitry which allows for the partial conversion of the supplied electricity to take place.

Identification of electrical power supply wiring as an avenue for heat external to the solid-state device to invade the inner workings of solid-state devices was made by Zimmermann, U.S. Pat. No. 3,248,889, issued May 3, 1966. The Zimmermann (col. 1, line 11) “ . . . invention relates to thermoelectric cooling devices. When the temperature of the current-supply leads in such a device lies higher than that of the first semiconductor section secured thereto, heat flows through this path into the device and must be dissipated again through the heat-exchanger. This requires either larger proportioning of the heat-exchanger or, if the heat-exchanger remains unchanged, the output of the cooling element is decreased.” (col. 1, line 33) “In a Peltier cooling device of the type hereinabove disclosed, these disadvantages are avoided and an unwanted thermal flow through the supply leads may be prevented if, according to the invention, at least one current-supply lead includes a Peltier element, the cold side of which is connected to the cooling device. Thus, due to thermoelectric action in the supply lead, the required temperature level is maintained so that an interfering thermal flow is prevented. . . . The transfer of mechanical forces between the supply leads and the Peltier device may thus be avoided without the increase in temperature caused by the flow of current in the lead of smaller cross-section being a source of interference.” The present invention applies Zimmermann's teachings not to block the ingress of ambient heat into the interior of a thermoelectric device but to use the electric supply leads and interior circuitry itself as a conduit or avenue to transport unwanted heat, for extracting or moving thermal energy generated during the operation of solid-state or LED components out of said solid-state or LED components' near-environment and effect a transfer of thermal energy thru insulating barriers protecting said solid-state or LED components from ambient conditions.

Paraphrasing my co-invented filing PCT/IS2003/000032 WO 2004/038290 A1, Jonsson et al., entitled “LED ILLUMINATED LAMP WITH THERMOELECTRIC HEAT MANAGEMENT”, and using as an example only, typically encountered solid-state devices: (page 1, line 11) “Practical design and application of . . . ” solid-state type devices . . . are limited by thermal energy-management issues.” Solid-State “ . . . device manufacturers have generally been aiming at developing . . . devices that provide greater . . . output without significant increase in size of the device. This accentuates the problem of heat management; the energy efficiency . . . is relatively low, such that only a portion of the consumed energy is converted . . . while the bulk of the energy is converted into heat. Therefore . . . more thermal energy is produced in the same unit volume of the device.” (page 1, line 21) “It is known that . . . ” most solid-state devices “ . . . exhibit negative temperature coefficient aspects, i.e. at fixed power input, as the device's operating heat rises, the device's . . . output decreases. The relationship between . . . decrease in . . . output due to increased operation temperature can be expressed approximately as a negative linear relationship between the percentage . . . output and degree C. increase in temperature.” (page 1, line 30) “Attempts have been made in the prior art to solve the negative temperature coefficient issues.”

An example of the abovementioned solid-state devices is taught by Gold, et al. in U.S. Pat. No. 6,937,958, issued Aug. 30, 2005. Gold teaches that “(t)emperature gradients across the dies of today's high performance very large scale integration (VLSI) components, such as a microprocessor, can adversely affect component performance. For example, a temperature variation between two clock driver circuits within a microprocessor often results in a skew in the system clock of the microprocessor.” “Given the size and complexity of integrated circuits, such as microprocessors, it is extremely difficult to determine and monitor a temperature gradient across the integrated circuit using only a single diode positioned at a location in the die of the integrated circuit. As such, substantial variations in temperature across the die of the integrated circuit can go undetected. Consequently, early indications that a thermal problem exists in a portion of the integrated circuit go undetected.”

There are significant advantages to suppressing internal operating temperatures of some solid-state devices. There are solid-state devices which exhibit a greater than a linear relationship to desired output for each unit of input energy as the operating temperature is decreased. As such, total energy consumed per unit of desired output is reduced as operating temperature is suppressed. Paraphrasing again from the abovementioned filing (PCT/IS2003/000032): (page 8, line 1) “It will be appreciated that the device of invention is able to produce more . . . ” output “ . . . per unit energy consumed, than corresponding . . . ” devices “ . . . without cooling, because the additional energy needed to operate the TEC is less than the . . . output gained.”

That said, the present invention, unlike my abovementioned filing, again paraphrasing the abovementioned filing (PCT/IS2003/000032), does not use a separate (page 8, line 11) “ . . . interface of thermally conducting material . . . ” between the solid-state device and the thermoelectric units but rather the same conducting material, as per Zimmermann, that supplies electricity to the solid-state device.

The present invention application of the Thomson Effect and enhancement of said Thomson Effect via present art thermoelectric devices to solid-state devices' electrical-circuitry, utilizing different materials/metals allows for enhanced cooling or heating of said circuitry. Quoting from Solid State Physics, by Om Prakash Pahuja, page 216, “Thomson Effect. “The emission or absorption of heat when a current is passed through a single conductor heated unequally along its length, is called Thomson effect. In metals, such as copper, silver, zinc, antimony and cadmium, heat is evolved when current flows from hot to cold side and heat is absorbed when the current is reversed. In such cases, the Thomson effect is said to be positive. In substances, such as iron, cobalt, nickel, platinum and bismuth, the heating and cooling effects are just reversed and hence the Thomson effect is said to be negative. In Lead, the Thomson effect is neither positive or negative, i.e., the effect is absent.” “Free electron theory can explain this effect partially. If a current is passed through a conductor whose one end is at a higher temperature than the other, in the direction from hot to cold end, electrons will be transferred from cold to hotter parts. The hotter part will increase the kinetic energy of these transferred electrons and hence heating effect will be produced. But at the same time, due to higher electronic pressure at the hotter end . . . electrons will move towards the colder part, where they have least energy and hence cooling effect is produced.”

The Thomson Effect is well established present art. Quoting from a hundred year old text, Electrical Engineering In Theory And Practice, by Aspinall Parr, page 387, “The Thomson Effect is that discovered by Sir W. Thomson (Lord Kelvin), who found that a length of the same material, if hotter at one end than the other, is heated more by a current from an outside source flowing in one direction through it than if the same current flows in the opposite direction. Also that heat is absorbed or evolved from a conductor, according to the material it is made of, by the passage of a current through it when its ends are at different temperatures. For example, heat is absorbed by a copper conductor when a current flows from the cold to the hot end, and evolved when the current is reversed in direction.”

The present invention incorporates the teachings of Tesla via his U.S. Pat. No. RE11,865, reissued Oct. 23, 1900 and provides novel thermally sensitive phase-change electrically conductive/non-conductive component(s) power supply leads/circuitry for effecting thermal-energy-management of saidsame devices and extraction and/or injection of thermal-energy thru/into saidsame devices and control of such devices, as well as present art solid-state devices is achieved by applying the present inventor's U.S. Pat. No. 6,705,744, issued Mar. 16, 2004, to Hubbell, et al. (Hubbell '744) methods of control of “ . . . phase-shifts of material(s)' states (gas to liquid, liquid to solid), shifting . . . transmissibility” to Tesla, who teaches (page 1, line 10) “It has long been known that many substances which are more or less conducting when in the fluid condition become insulators when solidified. Thus water, which is in a measure conducting, acquires insulating properties when converted into ice. The existing information on this subject, however, has been heretofore of a general nature only and chiefly derived from the original observations of Faraday, who estimated that the substances upon which he experimented, such as water and aqueous solutions, insulate an electrically-charged conductor about one hundred times better when rendered solid by freezing, and no attempt has been made to improve the quality of the insulation obtained by this means or to practically utilize it for such purposes as are contemplated in my present invention. In the course of my own investigations, more especially those of the electric properties of ice, I have discovered some novel and important facts, of which the more prominent are the following: first, that under certain conditions, when the leakage of the electric charge ordinarily taking place is rigorously prevented, ice proves itself to be a much better insulator than has heretofore appeared; second, that its insulating properties may be still further improved by the addition of other bodies to the water; third, that the dielectric strength of ice or other frozen aqueous substance increases with the reduction of temperature and corresponding increase of hardness, and fourth, that these bodies afford a still more effective insulation for conductors carrying intermittent or alternating currents, particularly of high rates, surprisingly thin layers of ice being capable of withstanding electromotive forces of many hundreds and even thousands of volts. These and other observations have led me to the invention of a novel method of insulating conductors, rendered practicable by reason of the above facts and advantageous in the utilization of electrical energy for industrial and commercial purposes.” (page 1, line 56) “This method consists in insulating an electric conductor by freezing or solidifying and maintaining in such state the material surrounding or contiguous to the conductor, using for the purpose a gaseous cooling agent circulating through one or more suitable channels extending through or in proximity to the said material.” (page 1, line 64) “In the practical carrying out of my method I may employ a hollow conductor and pass the cooling agent through the same, thus freezing the water or other medium in contact with or close to such conductor, or I may use expressly for the circulation of the cooling agent an independent channel and freeze or solidify the adjacent substance in which any number of conductors may be embedded. The conductors may be bare or covered with some material which is capable of keeping them insulated when it is frozen or solidified. The frozen mass may be in direct touch with the surrounding medium, or it may be in a degree protected from contact with the same by an inclosure more or less impervious to heat. The cooling agent may be any kind of gas, as atmospheric air, oxygen, carbonic acid, ammonia, illuminating-gas, or hydrogen. It may be forced through the channel by pressure or suction produced mechanically or otherwise. It may be continually renewed or indefinitely used, being driven back and forth or steadily circulated in closed paths under any suitable conditions as regards pressure, density, temperature, and velocity.” (page 2, line 27) “In many cases it will be of advantage to cover the hollow conductor with a thick layer of some cheap material, as felt, . . . Such a covering, penetrable by water, would be ordinarily of little or no use; but when embedded in the ice it improves the insulating qualities of the same. In this instance it furthermore serves to greatly reduce the quantity of ice required, its rate of melting, and the influx of heat from the outside, thus diminishing the expenditure of energy necessary for the maintenance of normal working conditions.” (page 2, line 43) “Generally considered, the cooling agent will have to carry away heat at a rate sufficient to keep the conductor at the desired temperature and to maintain a layer of the required thickness of the substance surrounding it in a frozen state, compensating continually for the heat flowing in through the layer and wall of the conductor and that generated by mechanical and electrical friction.” (page 2, line 81) “As to the temperature of the conductor, it will be determined by the nature of its use and considerations of economy. For instance, if it be employed for the transmission of telegraphic messages, when the loss in electrical friction may be of no consequence, a very low temperature may not be required; but if it be used for transmitting large amounts of electrical energy, when the frictional waste may be a serious drawback, it will be desirable to keep it extremely cold. The attainment of this object will be facilitated by any provision for reducing as such as possible the flowing in of the heat from the surrounding medium. Clearly the lower the temperature of the conductor the smaller will be the loss in electrical friction; but, on the other hand, the colder the conductor the greater will be the influx of heat from the outside and the cost of the cooling agent. From such and similar considerations the temperature securing the highest economy will be ascertained.” (page 4, line 67) “Generally in the transmission of electrical energy in large amounts . . . ” (page 4, line 82) “ . . . when the saving of electrical energy in the transmission is most important consideration or when the chief object is to reduce the cost of the mains by employment of cheap metal, as iron or otherwise, every effort will be made to maintain the conductors at the lowest possible temperature . . . ” (page 4, line 96) “From the above description it will be readily seen that my invention forms a fundamental departure in the principle from the established methods of insulating conductors employed in the industrial and commercial application of electricity. It aims, broadly, at obtaining insulation by the continuous expenditure of a moderate amount of energy instead of securing it only by virtue of an inherent physical property of the material used as heretofore. More especially, its object is to provide, when and wherever required, insulation of high quality, of any desired thickness, and exceptionally cheap, and to enable the transmission of electrical energy under conditions of economy heretofore unattainable and at distances until now impracticable by dispensing with the necessity of using costly conductors and insulators.”

Tesla's contemporary Steinmetz (Theory and Calculation of Electric Circuits) teaches 1917 electric conductor present art: (Page 1) “ . . . metallic conductors are those conductors in which the conduction of the electric current converts energy into no other form but heat. That is, a consumption of power takes place in the metallic conductors by conversion into heat, and into heat only. Indirectly, we may get light, if the heat produced raises the temperature high enough to get visible radiation as in the incandescent lamp filament, but this radiation is produced from heat, and directly the conversion of electric energy takes place into heat.” (Page 2) “A characteristic of metallic conductors is that the resistance is approximately constant, varying only slightly with the temperature, and this variation is a rise of resistance with increase of temperature—that is, they have a positive temperature coefficient.” (Page 4) “Characteristic of the electrolytic conductors is the negative temperature coefficient of resistance; the resistance decreases with increasing temperature—not in a straight, but in a curved line . . . ” (Page 10) “ . . . metallic conductors as well as the electrolytic conductors give a volt-ampere characteristic in which, with increase of current, the voltage rises, faster than the current in the metallic conductors, due to their positive temperature coefficient, slower than the current in the electrolytes, due to their negative temperature coefficient.” “The characteristic of the pyroelectric conductors, however, is such a very high negative temperature coefficient of resistance, that is, such rapid decrease of resistance with increase of temperature, that over a wide range of current the voltage decreases with increase of current.” (Page 28) “ . . . vapor, gas and vacuum conduction. Typical of this is, that the volt-ampere characteristic is dropping, that is, the voltage decreases with increase of current . . . ” “ . . . gas and vapor conductors are unstable on constant-potential supply, but stable on constant current . . . ” “Such conduction may be divided into three distinct types: spark conduction, arc conduction, and true electronic conduction.” “In true electronic conduction, electrons existing in the space, or produced at the terminals (hot cathode), are the conductors. Such conduction thus exists also in a perfect vacuum, and may be accompanied by practically no luminescence.” (Page 41) “The various classes of conduction: metallic conduction, electrolytic conduction, pyroelectric conduction, insulation, gas vapor and electronic conduction, are only characteristic types, but numerous intermediaries exist, and transitions from one type to another by change of electrical conditions, of temperature, etc.” “As regards to the magnitude of the specific resistance or resistivity, the different types of conductors are characterized about as follows:” (Page 42) “The resistivity of metallic conductors is measured in microohm-centimeters. The resistivity of electrolytic conductors is measured in ohm-centimeters. The resistivity of insulators is measured in megohm-centimeters and millions of megohm-centimeters. The resistivity of typical pryoelectric conductors is of the magnitude of that of electrolytes, ohm-centimeters, but extends from this down toward the resistivities of metallic conductors, and up toward that of insulators. The resistivity of gas and vapor conduction is of the magnitude of electrolytic conduction: arc conduction of the magnitude of lower resistance electrolytes . . . . Electronic conduction at atmospheric temperature is of the magnitude of that of insulators; . . . ”

Expression of application of Tesla's teachings at the nano-scale, allowing the present invention's operation to nano-scale devices can be found in U.S. Air Force SBIR Proposal # AF071-183, Title: Nanofluids for Heat Transfer Enhancement . . . . Quoting, in part, from said SBIR Proposal, “Thermal engineers strive constantly to improve the performance of the thermal management (TM) systems . . . . New materials and processes are candidate improvement strategies . . . . Nanofluids (NFs) are evolving coolant materials which offer the potential for heat transfer performance enhancements. This concept for improving the thermophysical properties of coolants is a fairly new research area. NFs have been found to exhibit up to 150 percent higher thermal conductivity and 3 times enhancement in critical heat flux (CHF) compared to the basic fluids from which the NFs are produced. A variety of finer nanoparticles are available commercially in substantial quantities to enable the production of NF suspensions. A wealth of research data is available in this new area to start exploring the benefits in real application scenarios. . . . The advent of nanoparticles processing methods and their unique properties (such as thousand times larger surface-to-volume ratio and ability to remain in suspension indefinitely) spawned the idea of designer-coolant development using carbon nanotube (CNT), Al2O3, Cu, CuO, etc. in coolants such as poly alpha olefin (PAO), water, and ethylene glycol.”

Monitoring the thermal gradients, and responding to such thermal gradient to modify such thermal gradients in three-dimensional solid-state devices has been the subject of a number of U.S. Patents since the advent of the solid-state era. An example of such teachings is U.S. Pat. No. 2,856,160, issued Oct. 14, 1958, to Kaye & Hatsopoulos. Kaye & Hatsopoulos teach that (col. 1, line 19) “(g)enerally, various forms of temperature control devices attempting to maintain a given surface at a constant and uniform temperature are activated by means of a surface “average-temperature” error.” (col. 1, line 36) “The use of a thermostatic type of control system in connection with an isothermal surface presents still other shortcomings. As noted before, it is characteristic of such systems that a change or error in temperature must occur before a correction signal can be sensed. Hence, the response of the control system is largely one of temperature compensation which depends on the thermal lag or time delay of the entire system to correct the actuating error. In practical applications the effect of these thermal lags is generally an overshoot of the temperature response.” (col. 1, line 49) “ . . . conventional type of feedback control is largely limited to a system dependent mainly on one variable, such as time, to achieve any degree of constancy of surface temperature. If the system depends on more than one variable, such as space as well as time, thermostatic temperature control becomes meaningless due to local heat flux variations unless one specifies each surface element to be maintained at a desired temperature. Since three-dimensional spatial temperature gradients and time gradients co-exist in many applications, and since the surface in question can be subjected to variable and non-uniform heat transfer rates, it is impractical to designate and control every surface element. Consequently, the thermostatic method of surface temperature control is inadequate for a multi-dimensional system.” Another example is U.S. Pat. No. 3,308,629, issued Mar. 14, 1967, to Sharp. Sharp teaches that (col. 1, line 19) “In the application to the measure of standard voltage reference cells it is desired to maintain . . . temperature at a precisely controlled standard temperature . . . and accurate to 0.001O C. . . . This is most difficult.” (col. 1, line 24) “Other variables are introduced into conventional temperature control systems where it is necessary to sense or measure a system temperature and in response thereto to activate or deactivate a heating or cooling source. Electrical contacts for such heating or cooling sources often chatter under such conditions giving a “saw-tooth” temperature curve which over-shoots and under-shoots the temperature control point. Such electrical contacts also tend to wear and to change characteristics with time, adding to the problems of temperature control.”

The present invention incorporates the present inventor's U.S. Pat. No. Hubbell '279, which is foreshadowed by the present inventor's U.S. Pat. No. 6,422,714, issued Jul. 23, 2002, which reads in part (col. 3, line 66) “The photosensors 28 and 30 advantageously extend the life . . . by minimizing the time . . . on.” Paraphrasing Hubbell '279 (col. 2, line 39) “ . . . to provide (a) device . . . whose . . . output can be maintained at a constant level by use of feedback illumination measuring equipment configurations . . . ” (col. 2, line 64) “This is important . . . because heat-build-up can cause both permanent and temporary . . . -output degradation and reduced-life-expectancy . . . ” (col. 6, line 5) “The . . . output of the . . . cluster 2 or . . . panel may (be) monitored with a sensor 46, whose output is fed to a controller 48 and is used to control a power source 50 connected to the . . . cluster 2. The output of the power source is appropriately adjusted to maintain the . . . output of the . . . cluster at the desired level.” (col. 6, line 11) “The sensor 46 may be disposed so as to measure the overall area . . . and (a) specific . . . section . . . . The sensor 46 may also measure the . . . output of individual . . . emitting sources within specific . . . emitting source groupings by sampling the actual (heat) generated by predetermined individual . . . emitting sources. Selection is determined by the statistical requirements of the individual . . . grouping in question and/or the required configuration, pattern and/or the relative importance of . . . maintenance.” (col. 6, line 21) “ . . . output may also be measured at the . . . interior, the boundary between two or more (devices), . . . ” (col. 6, line 25) “The sensor 46 may also measure the specific (heat) intensity generated by each . . . clusters, since shifts in intensity will produce shifts in total wavelength configuration, changing the . . . total . . . output. Different . . . clusters experience different . . . output degradation that, will cause (output) shifts over time. Furthermore, (solid-state devices) suffer from both a permanent decline of . . . output over time, for a given power input level and temporary increases and decreases in . . . output due to changes in local environment of ambient temperature, humidity, etc. In addition, minor shifts in quality of the power supply, such as slight drops in voltage, can also shift the . . . output . . . sources.” (col. 6, line 39) “With the disclosed feedback control, energy radiation, light intensities and appropriate combination of wavelengths provided by different . . . panels and/or other radiation sources can be adjusted to maximize energy radiation or light penetration of the medium separating the light source and the target surface and/or target volume.”

Use of Hubbell '279 means and methods allows incorporation of the present inventor's U.S. Pat. No. Hubbell '744. Hubbell '744 teaches that (col. 10, line 1) “(t)here are two responses to exo-system influences . . . , in cases of physical loadings, and/or localized environmental aspects affecting radiation . . . output . . . , such as heat, degradation, power supply, and/or changes to the targeted surface(s) and/or volume(s) such as phase-shifts of material(s)' states (gas to liquid, liquid to solid), shifting reflectivity, and/or transmissibility. The first response case assumes a passive design approach whereby the design engineer anticipates and provides for the exo-system influences . . . . The second response case assumes an active feedback of information about the conditions at the . . . surface(s) and/or volume(s) with the system-response adjusting either the . . . target surface(s) and/or volume(s) and/or system-response adjusting the intensity(ies) of one or more point-sources of radiation . . . ” Hubbell '744 provides, quoting claim 1, “A method for calculating the illumination intensity on a target surface provided by a plurality of light sources disposed in one location above the target surface, each light source providing a cone of light where the axis of the cone has the highest light intensity and the boundary of the cone represents a lesser percentage of the wavelength radiation intensity from the center, comprising: a) subdividing the target surface into grids; b) for each grid, calculating the light intensity provided by each light source by taking the cross product of a location vector represented by a line connecting the light source and the grid, and an aiming vector represented by the cone axis; c) calculating the angle between the location vector and the aiming vector; d) if the angle is less than one-half the cone angle, calculating the primary lighting intensity at the grid; e) plotting the total light intensity at each grid.” The present invention incorporates the Hubbell '744 method by capturing, in three-dimensions, selected wavelength radiation, such as infrared, generated from the surface of a solid-state device to, for example, model said device's internal, three-dimensional, thermal-gradient profiles, predict future thermal-states and select appropriate response(s).

Use of Hubbell '279 and '744 allows analysis and response, thru the above-mentioned aspects of the present invention, to perceived thermal gradients in three-dimensional solid-state devices to effect global and/or sector changes in said solid-state devices thermal state in three dimensions and thereby provide control of said device's desired output not available in the present art.

### OBJECT AND SUMMARY OF THE INVENTION

It is an object of the present invention to provide a thermal-energy-management device that controls, provides, a relatively uniform thermal intensity throughout the full length, width and depth of a solid-state device section.

It is another object of the present invention to provide a thermal-energy-management device that can retro-fit existing solid-state devices.

It is an object of the present invention to provide a thermal-energy-management device that provides a decrease in total energy consumed for a given unit of intended output of a given solid-state device.

It is another object of the present invention to provide precise placement of thermal-gradient(s) in the targeted solid-state area and/or volume.

It is still another object of the present invention to provide a thermal-energy-management device that uses thermal signature output to maintain at a designed output level by use of feedback thermal signature measuring equipment configurations.

It is another object of the present invention to provide a thermal-energy signature and/or other wavelength radiation methodology that allows the designer to provide a change in temperature to the solid-state target area/volume and restrict the thermal-energy levels of individual sources of unwanted heat, to provide desired thermal-energy intensity pattern desired within said target area/volume.

It is still another object of the present invention to provide a thermal-energy signature and/or other wavelength radiation methodology that allows the designer to create more tightly contrasting thermal-energy gradient intensities over a large well defined solid-state target area and/or volume.

It is still another object of the present invention to utilize portions of circuitry not in use for a given output to provide an avenue for heat extraction or injection into the solid-state device to be thermal-energy-managed.

It is an object of the present invention to effect phase-change of/in specific section(s) of a given solid-state device(s)' components, by way of thermal-energy-management and thereby influence said solid-state device(s)' output.

The present invention utilizes solid-state components'/devices' electrically-conductive elements as means for transport of thermal-energy via the application of the Thomson Effect through affecting a change in temperature, such as in the electrical power supply leads, from the ambient temperature of said solid-state components/devices. Said application may be at electrical current characteristics below that required to energize said solid-state components/devices to achieve intended solid-state utility output. The present invention applies Tesla's phase-change conductive/non-conductive, both of an electrical and/or thermal nature, to the present art of solid-state electronics by offering electronic component/device design(s) incorporating phase-change conductive/non-conductive, both of an electrical and/or thermal nature, to individual integrated circuit elements, printed wiring boards, insulating layer(s), supporting structures and pillars for the optimizing of the thermal-energy-management of such components/devices such as multi-layered wiring board which have laminated structures with insulating layers and wiring layers alternately overlaid. The present invention utilizes the present inventor's patents '279 and '744 to analyze the three-dimensional thermal volumes of solid-state items and effecting change of temperature via said items' electrical pathway(s) and/or by effecting said pathways by altering the matter-phase of such pathways resulting in change in conductivity/non-conductivity, both of an electrical and/or thermal nature, of said pathways.

### BRIEF DESCRIPTIONS OF THE DRAWINGS

The following drawings explain aspects of the present invention:

FIG. 1, shows a solid-state component such as an LED, 1, with electric power supply leads 1a & 1b, with section(s) of one lead's external portion's temperature changed from the given ambient temperature by means independent, 2, from said solid-state component.

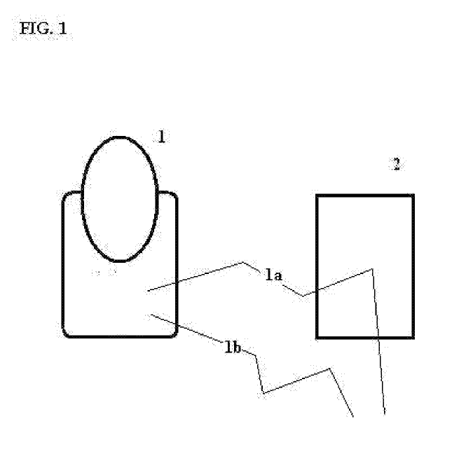

FIG. 2, is as FIG. 1, whereas the change from ambient temperature of the solid-state component's lead is via a thermoelectric device, 2a.

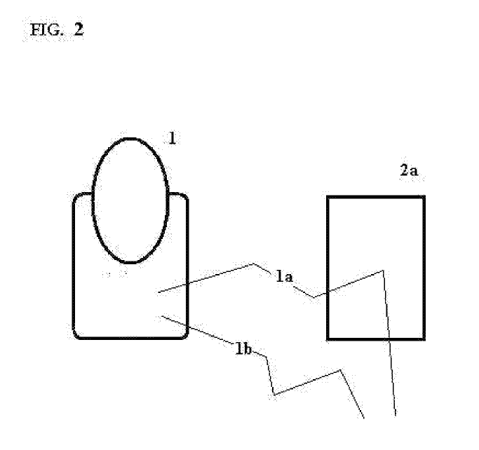

FIG. 3 is as FIG. 1, whereas sections of both leads of said solid-state component are changed from the given ambient temperature by means independent, 2, from said solid-state component

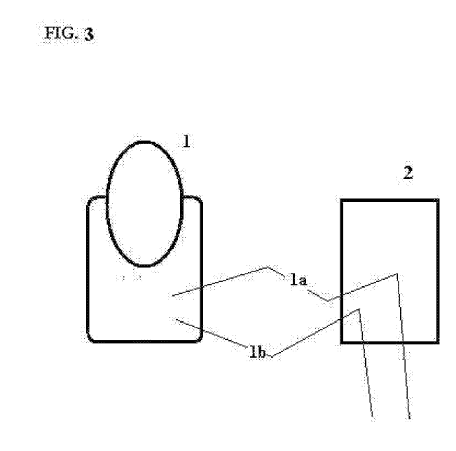

FIG. 4 is as FIG. 3, showing cascading independent means, 2 & 3, of changing said leads, 1a & 1b, from the given ambient temperature. FIG. 4 shows both leads, 1a & 1b, it being understood that said leads may be treated as independent from each other in a cascading arrangement.

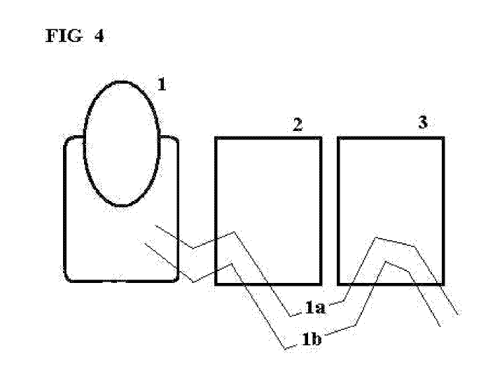

FIG. 5 shows a construction of a lead, such as 1a, or solid-state circuitry, section where boundary material 4 & 7 holds material 5, and the electrical conductive material 6.

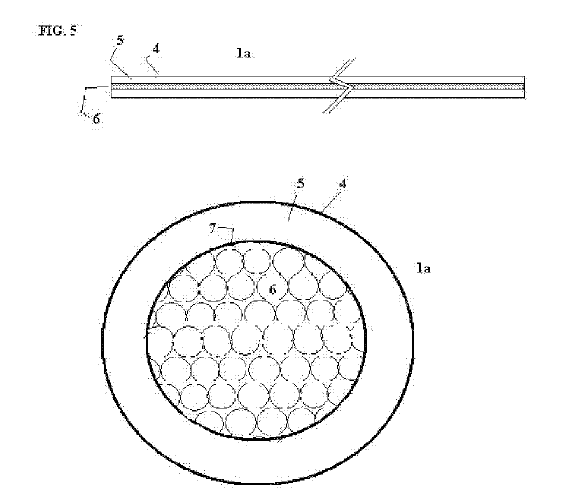

FIG. 6 shows a lead wherein electrical conductive material is bared, as seen in A-A, spread and sandwiched between elements, 2, of external temperature change device. Where said external temperature change device is a thermoelectric device and the intent of the design is to chill said lead(s) and/or circuitry, said temperature change device 2 will have cold-side, 8, sandwiching the electrical conductive material 6, with hot-side, 9, equipped to expel transferred heat energy.

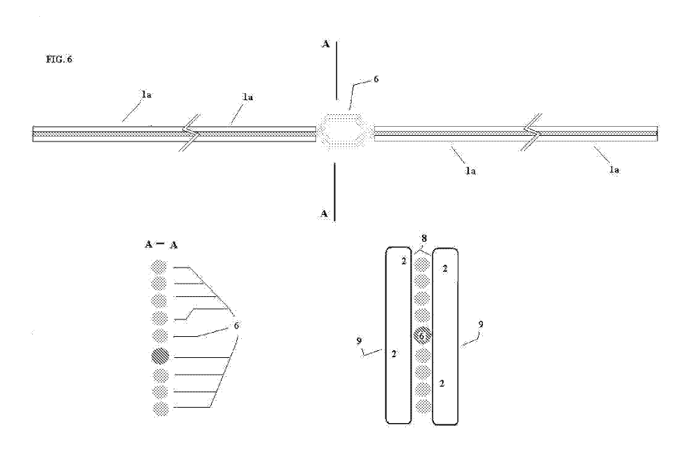

### EMBODIMENT OF THE INVENTION

A first embodiment of the present invention is a single solid-state junction type device such as an LED wherein one of said LED's electric power supply leads is chilled resulting in a Thomson Effect movement of thermal energy from said LED's selected chilled lead and via said lead chilling of said LED's solid-state circuitry before said LED's junction is energized. Present art commercially-available off-the-shelf (COTS) LEDs convert electric energy, thru junction(s), into light and heat. Said junction is electrically insulated as well as encapsulated. Said electrical insulation provides a de facto thermal insulation. Said thermal insulation creates a potential thermal-gradient between said junction(s) and the immediate environment external to said encapsulation. Pre-chilling before energization, among other aspects, retards the onset of detrimental increase in operating temperature after energization.

A second embodiment of the present invention is a single solid-state junction type device such as an LED wherein said LED's electric power supply leads are chilled resulting in a Thomson Effect movement of thermal energy from said LED's selected chilled lead and via said lead chilling of said LED's solid-state circuitry before said LED's junction is energized.

A third embodiment of the present invention is a single solid-state junction type device such as an LED wherein one or both said LED's electric power supply leads are chilled and energized below that required to effect the intended output of said LED resulting in an enhanced Thomson Effect movement of thermal energy from said LED's selected chilled lead and via said lead chilling of said LED's solid-state circuitry before said LED's junction is energized.

A fourth embodiment of the present invention is a single solid-state junction type device such as an LED wherein one or both said LED's electric power supply leads are chilled and energized at that required to effect the intended output of said LED resulting in an enhanced Thomson Effect movement of thermal energy from said LED's selected chilled lead and via said lead chilling of said LED's solid-state circuitry before said LED's junction is energized.

A fifth embodiment of the present invention utilizes a thermoelectric device to effect the abovereferenced chilling.

A sixth embodiment, utilizes the abovereferenced means and methods to affect the mentioned thermoelectric device.

A seventh embodiment, in reference to the above embodiments, incorporates, includes, in the LED's referenced leads and/or circuitry, Tesla's abovementioned device such as but not limited to (paraphrasing) “ . . . method of employing a hollow conductor and pass cooling agent through the same, thus freezing the water or other medium in contact with or close to such conductor, or may use expressly for the circulation of the cooling agent an independent channel and freeze or solidify the adjacent substance in which any number of conductors may be embedded. The conductors may be bare or covered with some material which is capable of keeping them insulated when it is frozen or solidified. The frozen mass may be in direct touch with the surrounding medium, or it may be in a degree protected from contact with the same by an inclosure more or less impervious to heat.”

An eighth embodiment utilizes Hubbell '279 and/or '744 to construct and analyze the abovementioned embodiments' three-dimensional heat signature and engage one or more of the abovementioned embodiments in a pre-set sequence to achieve a predetermined thermal state within the solid-state device, such as the LED mentioned above, or select one or more of the abovementioned embodiments on the basis of predicted changes in said solid-state device's physical points of waste-heat generation from said three-dimensional heat signature.

A ninth embodiment utilizes multiple aspects of the abovementioned embodiments where solid-state devices with multiple leads and/or layered circuitry type devices, such as VLSI components, replace the abovementioned solid-state LED in the above-mentioned embodiments.

A tenth embodiment utilizes Tesla's abovementioned means and methods to effect phase-changes in either the leads and/or circuitry and/or conductive pillars and/or insulating layer(s) of the solid-state device to be thermal-energy-managed. Such phase-changes being effected in changes in the said solid-state device's component(s) in conjunction with specific chilling or heating regime(s), resulting in changes in said device's component(s) electrical and/or thermal conductivity. Said changes in said device's component(s) electrical and/or thermal conductivity resulting in enhancing desired thermal energy management efforts and/or said devices' intended output(s).

A eleventh embodiment utilizes Tesla's abovementioned means and methods in concert with Hubbell '279 and/or '744 to effect phase-changes in either the leads and/or circuitry and/or conductive pillars and/or insulating layer(s) of the solid-state device to be thermal-energy-managed. Such phase-changes being effected in changes in the said solid-state device's component(s) via abovementioned utilization of Hubbell '279 and/or '744 in conjunction with specific chilling or heating regime(s), resulting in changes in said device's component(s) electrical and/or thermal conductivity. Said changes in said device's component(s) electrical and/or thermal conductivity resulting in enhancing desired thermal energy management efforts

### Preferred Embodiment

The preferred embodiment of the present invention is a single solid-state junction type device, such as an LED, wherein each of said solid-state electric power supply leads is individually chilled resulting in a Thomson Effect movement of thermal energy from selected leads resulting in a chilling of said solid-state's circuitry before said solid-state junction is energized.

While this invention has been described as having preferred design, it is understood that it is capable of further modification, uses and/or adaptations following the principle of the invention and including such departures from the present disclosure as comes within known or customary practice in the art to which the invention pertains, and as may be applied to the essential features set forth, and fall within the scope of the invention or the limits of the appended claims.

I claim:

1. The means and method of thermal management of electronic circuitry herein described which consists in imparting a change, in temperature of said circuitry, external to said circuitry.

2. As in claim 1, whereas said change in temperature is effected by action on said circuitry's electric power conductor(s).

3. As in claim 1, whereas said change in temperature is effected by action on said circuitry's electric power conductor(s) then said conductor(s) is energized.

4. As in claim 1, whereas said change in temperature is effected by action on said circuitry's electric power conductor(s) then said conductor(s) is energized below that required to energize said circuitry.

5. As in claim 1, wherein said change in temperature causes a phase-change in said conductor(s)

6. As in claim 1, wherein said change in temperature cause a phase-change in selected portions of said conductor(s).

7. As in claim 1, wherein said change in temperature causes a phase-change in said circuitry.

8. As in claim 1, wherein said change in temperature cause a phase-change in selected portions of said circuitry.

9. As in claim 1, wherein said change in temperature causes a phase-change in said conductor(s)' insulating material.

10. As in claim 1, wherein said change in temperature causes a phase-change in selected portions of said conductor(s)' insulating material.

11. As in claim 1, wherein said change in temperature causes a phase-change in said circuitry' insulating material.

12. As in claim 1, wherein said change in temperature causes a phase-change in selected portions of said conductor(s)' insulating material.

13. As in claim 1, minimizing byproduct parasitic heat of solid-state circuitry, such as LEDs and VLSI devices, operation as electric current energizes said circuitry.

14. As in claim 1, minimizing byproduct parasitic heat of solid-state circuitry, such as LEDs and VLSI devices, by pre-chilling said circuitry before electric current energizes said circuitry.

15. As in claim 1, a light illuminating device comprising at least one light emitting diode (LED) and at least one thermoelectric module (TEM) thermally connected to the LED's electrical power conduit.

16. As in claim 1, wherein said change, in temperature, in selected portions of said circuitry not energized, resulting in a temperature gradient effecting nearby portions of said circuitry that is energized

17. As in claim 1, whereas said circuitry's thermal state is detected, analyzed and specific temperature changing means engaged to maintain a predetermined state of thermal density.

18. As in claim 1, whereas selected portions of said insulating material of said circuitry provides different insulating properties when said selected portions are intentionally caused to phase-change.

19. As in claim 1, whereas selected portions of said conductive material of said circuitry provides different conductive properties when said selected portions are intentionally caused to phase-change.

20. As in claim 1, whereas the insulating materials of said circuitry consists in embedding the same in a moist or plastic compound which acquires insulating properties when in a frozen or solidified state, and maintaining the compound in such state by change of temperature of said circuitry.
